(19) United States
(12) Patent Application Publication
(10) Pub. No.: US 2025/0296834 A1
(43) Pub. Date: Sep. 25, 2025

(54) MICROELECTROMECHANICAL SYSTEMS DEVICE AND METHOD FOR FORMING THE SAME

(71) Applicants: TAIWAN SEMICONDUCTOR MANUFACTURING COMPANY, LTD., Hsinchu (TW); NATIONAL TSING HUA UNIVERSITY, Hsinchu City (TW)

(72) Inventors: Szu-Han CHEN, Kaohsiung City (TW); Weileun FANG, Hsinchu City (TW); Sheng Kai YEH, Taichung City (TW); Shih Chi LIU, Hsinchu City (TW); Chi-Yuan SHIH, Hsinchu County (TW); Shih-Fen HUANG, Hsinchu County (TW)

(73) Assignees: TAIWAN SEMICONDUCTOR MANUFACTURING COMPANY, LTD., Hsinchu (TW); NATIONAL TSING HUA UNIVERSITY, Hsinchu City (TW)

(21) Appl. No.: 18/612,937

(22) Filed: Mar. 21, 2024

(51) Int. Cl. B81B 7/02; B81C 1/00

(52) U.S. Cl. CPC B81B 7/02; B81C 1/00539; B81B 2201/04; B81B 2203/0118; B81B 2203/0163; B81B 2203/0307; B81B 2203/04; B81B 2203/058; B81B 2207/11; B81C 2201/0132; B81C 2201/0198

(57) ABSTRACT

A microelectromechanical systems (MEMS) device includes a mirror structure, a frame, a first cantilever, a second cantilever, and first to fourth transmission springs. The first cantilever includes a first electrode. The second cantilever includes a second electrode spaced apart from the first electrode. The mirror structure is suspended in the frame by the first cantilever and the second cantilever. The first transmission spring connects the first cantilever to a first end of the mirror structure. The second transmission spring connects the second cantilever to the first end of the mirror structure. The third transmission spring connects the first cantilever to a second end of the mirror structure. The fourth transmission spring connects the second cantilever to the second end of the mirror structure.

### BACKGROUND

Micro electro mechanical systems (MEMS) devices are known that have a mirror structure obtained using a semiconductor material technology. Such MEMS devices are, for example, used in portable apparatuses, such as portable computers, laptops, notebooks (including ultra-thin notebooks), PDAs, tablets, mobile phones or smartphones, for optical applications, in particular for directing one or more beams of light radiation generated by a light source in desired patterns and/or directions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of a microelectromechanical systems (MEMS) device in accordance with some embodiments of the present disclosure.

FIG. 1B is an enlarged view of a portion of FIG. 1A.

FIG. 2A is a top view of a MEMS device in accordance with some embodiments of the present disclosure.

FIG. 2B is an enlarged view of a portion of FIG. 2A.

FIG. 3A is a top view of a MEMS device in accordance with some embodiments of the present disclosure.

FIG. 3B is an enlarged view of a portion of FIG. 3A.

FIG. 4 is a schematic view of a MEMS device in accordance with some embodiments of the present disclosure.

FIGS. 5-12B are cross-sectional views of intermediate stages in formation of a MEMS device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

LiDAR (Light Detection and Ranging) has been widely used in various field, such as topography, three-dimensional imaging, spectroscopy. Recently, LiDAR have attracted much attention in the automotive field as the key component for high level self-driving systems. Compared with other technique of self-driving sensor, such as radar and stereo camera, LiDAR have the advantage of providing high accurate and high resolution in 3D surrounding measurement in harsh environment. Micro electro mechanical systems (MEMS) LiDAR has advantages of low cost through batch fabrication and high operation frequency, high resolution, low power consumption. Piezoelectric MEMS LiDAR further has advantages of low power consumption, compact size and large generated force.

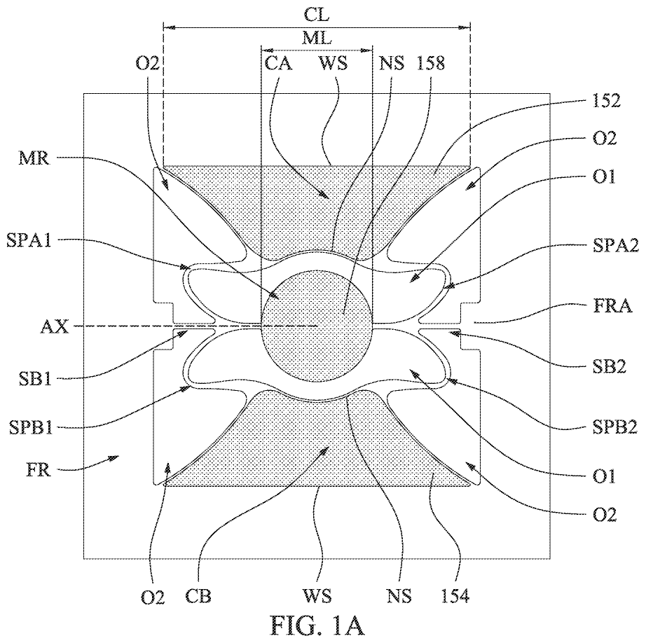

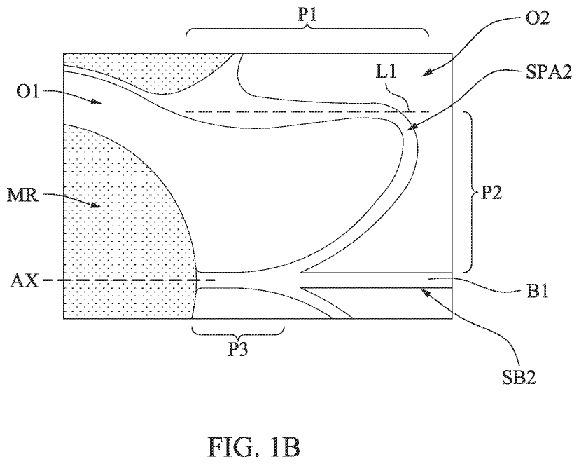

FIG. 1A is a top view of a microelectromechanical systems (MEMS) device in accordance with some embodiments of the present disclosure. The MEMS device may include a mirror region MR, a first cantilever region CA, a second cantilever region CB, connection regions SPA1 and SPA2, and a frame region FR. The mirror region MR is suspended, for example, being held apart from the frame region FR by the first cantilever region CA and the second cantilever region CB. The mirror region MR can rotate along a rotation axis AX. The first cantilever region CA and the second cantilever region CB may respectively include top electrodes 152 and 154. The first cantilever region CA and second cantilever region CB may serve as actuator that would deform and provide the driving force to rotate the mirror when the voltage is applied. The mirror region MR may include an electrode 158, which serve as a reflective mirror. The reflective mirror (i.e., the top electrode 158) and the top electrodes 152 and 154 may be patterned from a same top electrode layer. In the context, the first cantilever region CA, the second cantilever region CB, the mirror region MR, and the frame region FR can be respectively referred to as a first cantilever, a second cantilever, a mirror structure, and a frame.

The first cantilever region CA and the second cantilever region CB may extend across the mirror region MR along the rotation axis AX of the mirror region MR. For example, a length CL of the first cantilever region CA and the second cantilever region CB is greater than a length ML of the mirror region MR. The first cantilever region CA and the second cantilever region CB may have a shape tapering from the frame region FR to the mirror region MR. Stated differently, each of the first cantilever region CA and the second cantilever region CB may have a wide side WS facing and connected with the frame region FR (or facing away from the mirror region MR) and a narrow side NS facing and connected with the mirror region MR. The wide sides WS of the first cantilever region CA and the second cantilever region CB may be wider than the narrow sides NS of the first cantilever region CA and the second cantilever region CB. In some embodiments, the wide sides WS of the first cantilever region CA and the second cantilever region CB are wider than a diameter of the mirror region MR. In some embodiments, the narrow sides NS of the first cantilever region CA and the second cantilever region CB may have a concave profile corresponding to the profile of the mirror region MR.

In some embodiments of the present disclosure, the first cantilever region CA is fully operated by the top electrode 152 and electrically isolated from the top electrode 154, and the second cantilever region CB is fully operated by the top electrode 154 and electrically isolated from the top electrode 152. Thus, the top electrodes 152 and 154 would have the same configuration as the first cantilever region CA and the second cantilever region CB do, respectively. For example, the top electrodes 152 and 154 may extend across the mirror region MR along the rotation axis AX of the mirror region MR. For example, a length of the top electrodes 152 and 154 is greater than a length of the mirror region MR. The top electrodes 152 and 154 may have a shape tapering from the frame region FR to the mirror region MR. Stated differently, each of the top electrodes 152 and 154 may have a wide side WS facing the frame region FR (or facing away from the mirror region MR) and a narrow side NS facing the mirror region MR. The wide sides WS of the top electrodes 152 and 154 may be wider than narrow sides NS of the top electrodes 152 and 154. In some embodiments, the wide sides WS of the top electrodes 152 and 154 are wider than a diameter of the mirror region MR. In some embodiments, the narrow sides NS of the top electrodes 152 and 154 may have a concave profile corresponding to the profile of the mirror region MR.

The connection regions SPA1 and SPA2 may respectively connects two ends of the narrow side NS of the first cantilever region CA to opposite ends of the mirror region MR along the rotation axis. And, the connection regions SPB1 and SPB2 may respectively connect two ends of the narrow side NS of the second cantilever region CB to the opposite ends of the mirror region MR along the rotation axis. The connection regions SPA1, SPA2, SPB1 and SPB2 may also be referred to as transmission springs for transmitting driving force to the mirror region MR. The connection regions (transmission springs) SPA1, SPA2, SPB1, and SPB2 may have the curvature like hook shape. The connection regions (transmission springs) SPA1 and SPB1 would converge along the rotation axis AX. The connection regions (transmission springs) SPA2 and SPB2 would converge along the rotation axis AX.

The MEMS device may further include the shock buffer regions SB1 and SB2, which may be referred to as shock buffers. The shock buffer regions SB1 and SB2 connect opposite ends of the mirror region MR along the rotation axis AX to the frame region FR, thereby enhances the robustness of the device and reduce the wobbling phenomenon. The connection regions (transmission springs) SPA1 and SPB1 may be in contact with a shock buffer region SB1. The connection regions (transmission springs) SPA2 and SPB2 may be in contact with a shock buffer region SB2. The frame region FR may serve as an anchor for the mirror region MR through the shock buffer regions SB1 and SB2. Thus, the mirror region MR can be rotated with respect to the rotation axis AX. The shock buffer regions SB1 and SB2 may have elongated shape extending along the rotation axis AX. In some embodiments, the frame region FR may have anchor portions FRA extending from a main portion of the frame region FR, and the shock buffer regions SB1 and SB2 are connected with the anchor portions FRA. A width of the shock buffer regions SB1 and SB2 may be less than a width of the anchor portions FRA of the frame region FR. In some alternative embodiments, the anchor portions FRA of the frame region FR may be omitted, and the shock buffer regions SB1 and SB2 are directly connected with the frame region FR. The shock buffer SB1 and SB2 can increase the robustness of the out-of-plane of the mirror and reduce the wobbling phenomenon. In the present embodiments, the width of the shock buffer regions SB1 and SB2 may be substantially equal to a width of the connection regions (transmission springs) SPA1, SPA2, SPB1, and SPB2. In some alternative embodiments, the width of the shock buffer regions SB1 and SB2 may be greater or less than the width of the connection regions (transmission springs) SPA1, SPA2, SPB1, and SPB2.

FIG. 1B is an enlarged view of a portion of FIG. 1A. Reference is made to FIGS. 1A and 1B. In the present embodiments, each of the connection regions (transmission springs) SPA1, SPA2, SPB1, and SPB2 may include a first portion P1, a second portion P2, and a third portion P3. The first portion P1 is connected to the first cantilever region CA (or the second cantilever region CB), the third portion P3 is connected to the mirror region MR, and the second portion P2 connects the first portion P1 to the third portion P3. The third portion P3 may extend substantially along the rotation axis AX of the mirror region MR. The first portion P1 may extend along an imaginary extension line L1 substantially parallel with the rotation axis AX of the mirror region MR. In some embodiments, a length of the first portion P1 measured along the imaginary line L1 may be greater than a length of the third portion P3 measured along the rotation axis AX. The second portion P2 may be a curved line connecting the first portion P1 to the third portion P3. In some embodiments, the second portions P2 of the two connection regions (transmission springs) SPA2 and SPB2 may converge on the rotation axis AX, and may be in contact with the shock buffer region SB2. The second portions P2 of the two connection regions (transmission springs) SPA1 and SPB1 may converge on the rotation axis AX, and may be in contact with the shock buffer region SB1.

In some embodiments, an angle between the extension line L1 that the first portion P1 extends along and the rotation axis AX of the mirror region MR may be in a range from about 0 degrees to about 20 degrees. Similarly, an angle between an extension line that the third portion P3 extends along and the rotation axis AX of the mirror region MR may be in a range from about 0 degrees to about 20 degrees. If the angle is greater than 20 degrees, the forces, provided by the first cantilever region CA and the second cantilever region CB, transmitted to the mirror region MR, through the connection regions (transmission springs) SPA1, SPA2, SPB1, and SPB2, may be reduced.

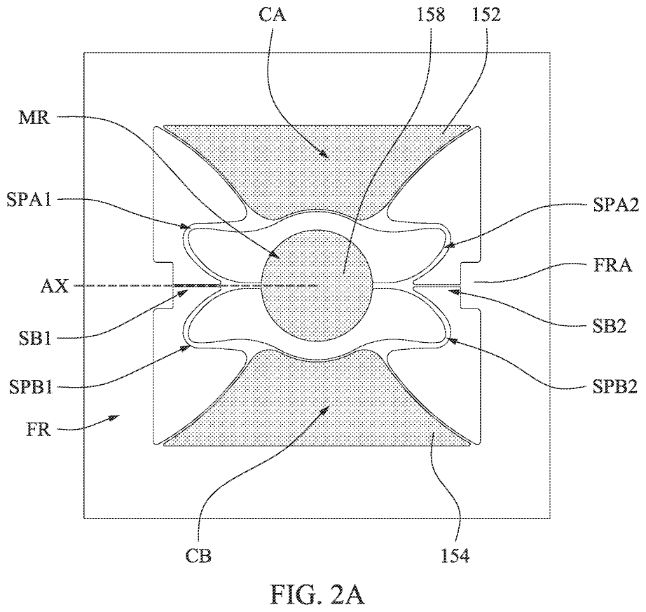

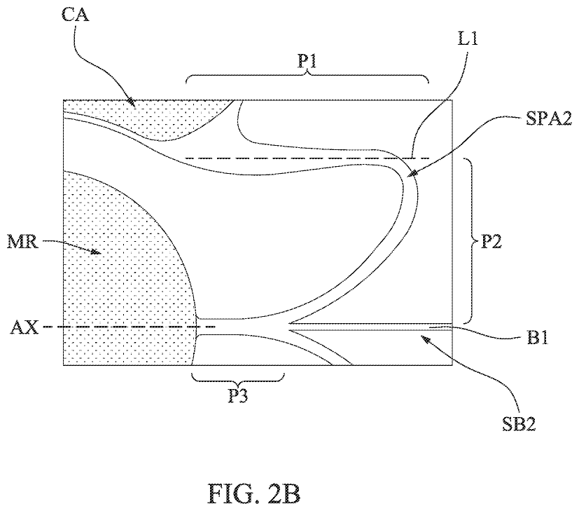

FIG. 2A is a top view of a MEMS device in accordance with some embodiments of the present disclosure. FIG. 2B is an enlarged view of a portion of FIG. 2A. Reference is made to FIGS. 2A and 2B. Details of the present embodiments are similar to those illustrated in FIGS. 1A and 1B, except that the width of the shock buffer regions SB1 and SB2 may be less than the width of the connection regions (transmission springs) SPA1, SPA2, SPB1, and SPB2. For example, a ratio of the widths of the shock buffer regions SB1 and SB2 to the widths of the connection regions (transmission springs) SPA1, SPA2, SPB1, and SPB2 may be in a range from about 0.1 to about 0.9. The reduction in the width of the shock buffer may lower the stiffness of structure, thereby lowering scanning frequency. Also, the reduction in the width of the shock buffer may lower the stiffness of structure, enlarge the rotational degree of freedom, thereby enhancing the performance of scanning angle. Other details of the present embodiments are similar to those previously illustrated, and thereto not repeated herein.

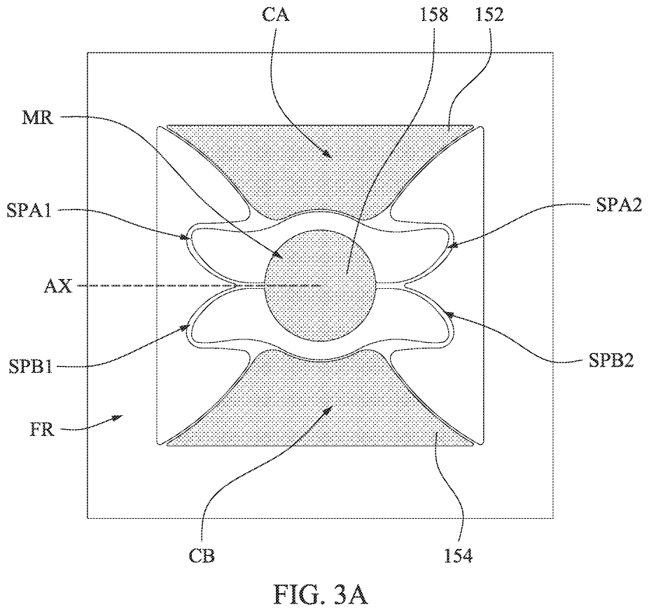

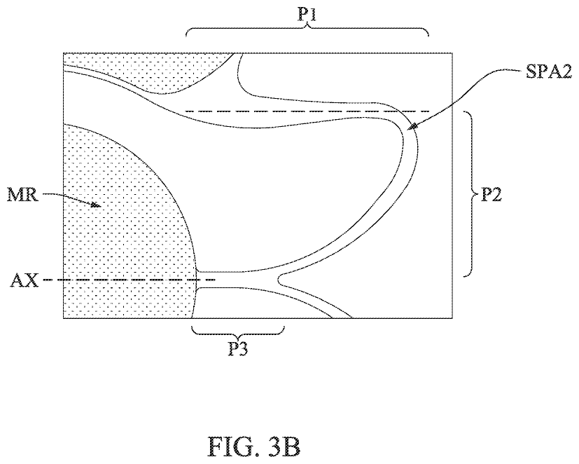

FIG. 3A is a top view of a MEMS device in accordance with some embodiments of the present disclosure. FIG. 3B is an enlarged view of a portion of FIG. 3A. Reference is made to FIGS. 3A and 3B. Details of the present embodiments are similar to those illustrated in FIGS. 1A and 1B, except that the shock buffer regions SB1 and SB2 are omitted. In the present embodiments, the second portions P2 of the two connection regions (transmission springs) SPA2 and SPB2 may converge on the rotation axis AX, and not be in contact with a shock buffer region connected to the frame region FR. Other details of the present embodiments are similar to those previously illustrated, and thereto not repeated herein.

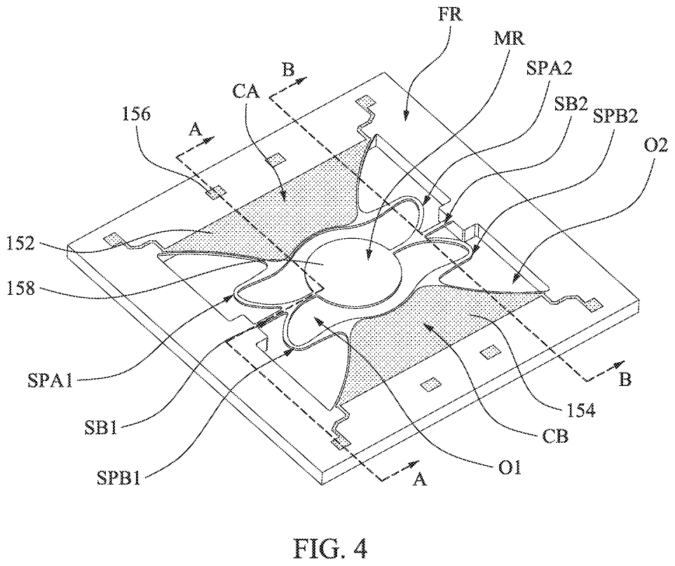

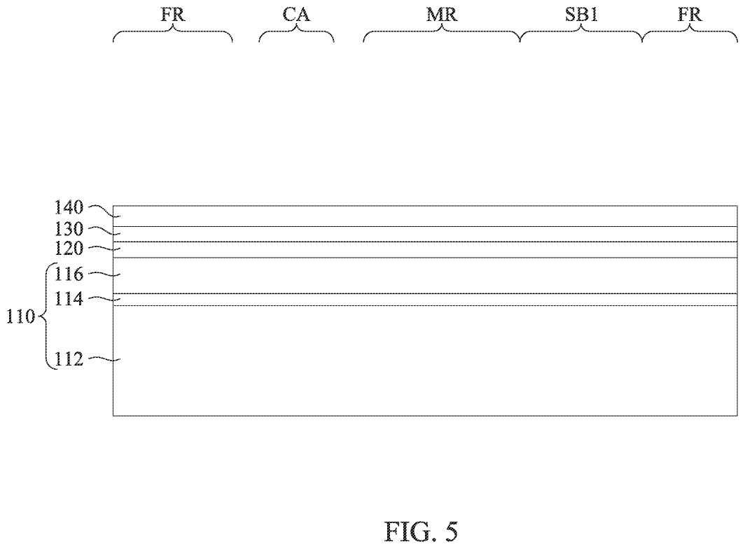

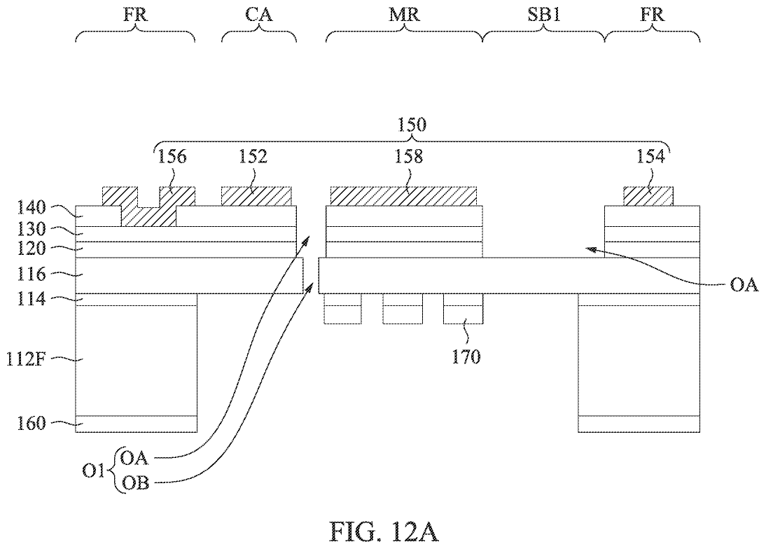

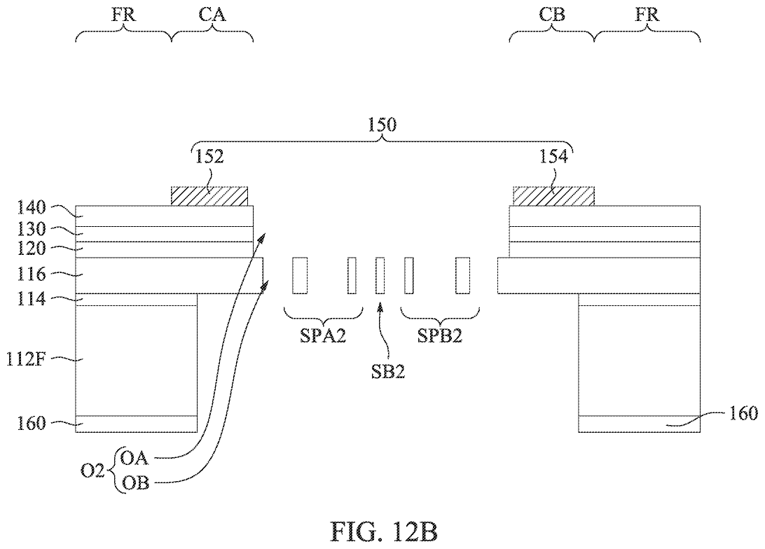

FIG. 4 is a schematic view of a MEMS device in accordance with some embodiments of the present disclosure. FIGS. 5-12B are cross-sectional views of intermediate stages in formation of a MEMS device in accordance with some embodiments of the present disclosure. The cross-sectional views of FIGS. 5-12A are taken along line A-A in FIG. 4. The cross-sectional view of FIG. 12B is taken along the line B-B in FIG. 4. It is understood that additional steps may be provided before, during, and after the steps shown by FIGS. 5-12B, and some of the steps described below can be replaced or eliminated for additional embodiments of the method. The order of the operations/processes may be interchangeable.

Reference is made to FIG. 5. A semiconductor substrate 110 is provided. The semiconductor substrate 110 may be a semiconductor-on-insulator (SOI) substrate including a base substrate 112, a dielectric layer 114 over the base substrate 112, and a semiconductor layer 116 over the dielectric layer 114. The base substrate 112 may be a bulk substrate, such as bulk silicon substrate. The base substrate 112 may include silicon. Alternatively, the base substrate 112 may include other elementary semiconductor such as germanium. The base substrate 112 may also include a compound semiconductor such as silicon carbide, gallium arsenic, indium arsenide, and indium phosphide. The base substrate 112 may include an alloy semiconductor such as silicon germanium, silicon germanium carbide, gallium arsenic phosphide, and gallium indium phosphide. The base substrate 112 may be referred to as a handle wafer in some embodiments. The dielectric layer 114 may include silicon oxide or other suitable insulating materials, and/or combinations thereof. In some embodiments, a dielectric layer 114 may include a buried oxide layer (BOX) that is grown or deposited overlying the silicon base substrate 112. The semiconductor layer 116 may include an elementary semiconductor, such as silicon (Si) or germanium (Ge) in a crystalline structure; a compound semiconductor, such as silicon germanium (SiGe), silicon carbide (SiC), gallium arsenic (GaAs), gallium phosphide (GaP), indium phosphide (InP), indium arsenide (InAs), and/or indium antimonide (InSb); or combinations thereof. For example, the SOI substrates are fabricated using separation by implantation of oxygen (SIMOX), wafer bonding, and/or other suitable methods. For clear illustration, in the cross-sectional views of some embodiments, the semiconductor substrate 110 is shown as including a first cantilever region CA, a mirror region MR, and shock buffer regions SB1, and a frame region FR.

A dielectric layer 120 is deposited over the semiconductor substrate 110. The dielectric layer 120 can be made of any suitable dielectric material, such as silicon oxide, silicon nitride, the like, or the combination thereof.

A bottom electrode layer 130 is deposited over the dielectric layer 120. The bottom electrode layer 130 may include suitable conductive materials, such as platinum, titanium, copper (Cu), gold (Au), the like, or the combination thereof.

A piezoelectric layer 140 is deposited over the bottom electrode layer 130. The piezoelectric layer 140 may include suitable piezoelectric materials, such as lead zirconate titanate (PZT), aluminum nitride (AlN), zinc oxide (ZnO), TiBaO₃, the like, or the combination thereof.

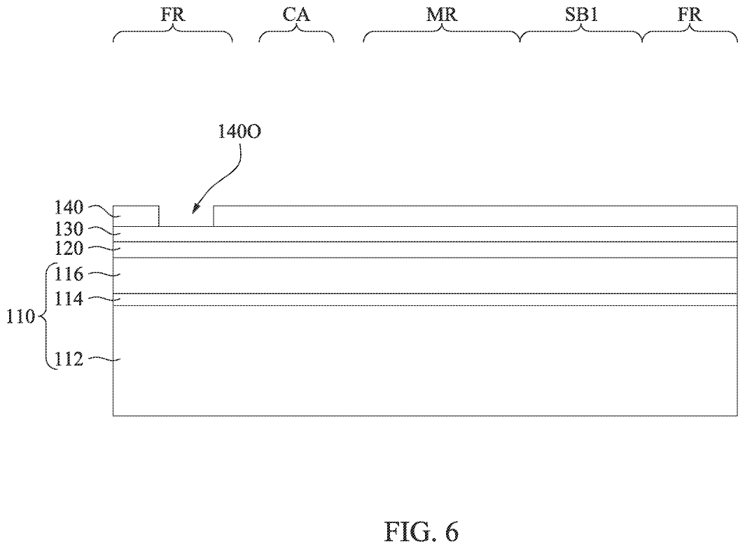

Reference is made to FIG. 6. The piezoelectric layer 140 is patterned to have one or more openings 1400 exposing the underlying bottom electrode layer 130. The patterning process may include forming a mask over the piezoelectric layer 140 by suitable photolithography process, followed by suitable etching process, such as wet etching.

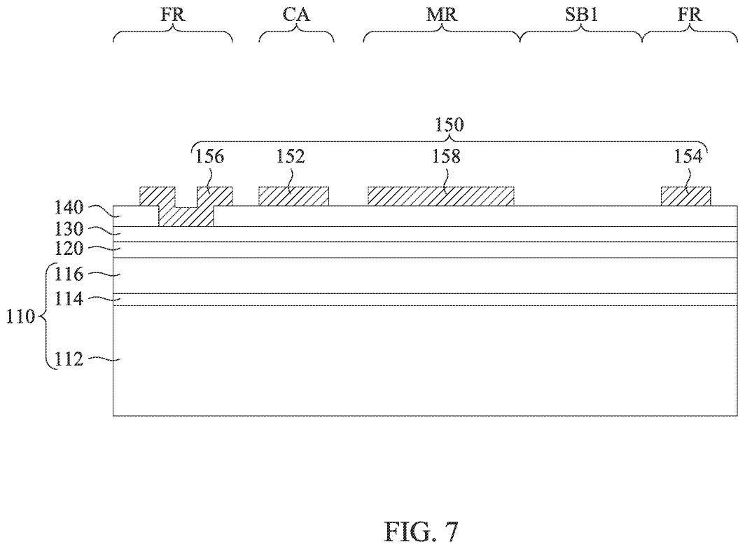

Reference is made to FIG. 7. A top electrode layer 150 is deposited over the piezoelectric layer 140, and patterned into separated top electrodes 152-158. The top electrode layer 150 may include suitable conductive materials, such as platinum, silver, copper (Cu), gold, chromium (Cr), the like, or the combination thereof. In some embodiments, the conductive materials of the top electrode layer 150 are chosen for achieving high reflectance in the operating wavelength range. The deposition process for the top electrode layer 150 may include an e-gun evaporation method. The patterning may include a lift-off process.

The top electrodes 152-158 are electrically isolated from each other. The piezoelectric layer 140 is sandwiched between the top electrodes 152, 154, and 158 of the top electrode layer 150 and the first bottom electrode layer 130. The top electrodes 152-154 and 158 are spaced apart from the first bottom electrode layer 130. The top electrodes 152 and 154 may be located in the first cantilever region CA and the second cantilever region CB to provide a vertical displacement of actuators through exerting different voltage phase across different regions of the piezoelectric layer 140, thereby providing (rotational/twist) forces to the mirror region MR. Stated differently, voltages with phase variation may be applied on the top electrodes 152 and 154 respectively for providing (rotational/twist) forces to the mirror region MR. For example, a positive voltage is applied on the top electrode 152, and a negative voltage is applied on the top electrode 154. Alternatively, a positive voltage is applied on the top electrode 154, and a negative voltage is applied on the top electrode 152. The top electrodes 152/154 of the two cantilever regions CA and CB can be applied with different voltages for individually operation and control. The top electrode 156 may extend into the openings 1400 in the piezoelectric layer 140. The top electrode 156 is in contact with the first bottom electrode layer 130 for serving as conductive paths/pads to the first bottom electrode layer 130. The top electrode 158 may serve as a reflective mirror. The top electrodes 152 and 154 may extend into the frame region FR to serve as conductive paths/pads for connection.

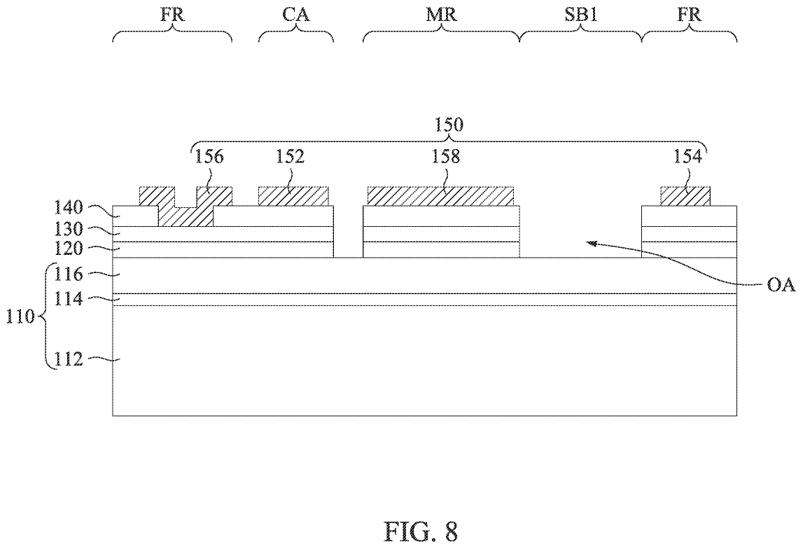

Reference is made to FIG. 8. The openings OA are etched in the piezoelectric layer 140, the bottom electrode layer 130, and the dielectric layer 120. The etching process may include reactive-ion etching (RIE) process, such as an inductively coupled plasma (ICP) etching process. After the etching process, the semiconductor layer 116 may remain substantially intact. The formation of the openings OA may remove the materials of the piezoelectric layer 140, the bottom electrode layer 130, and the dielectric layer 120 from the connection regions SPA1, SPA2, SPB1 and SPB2 and the shock buffer regions SB1, SB2.

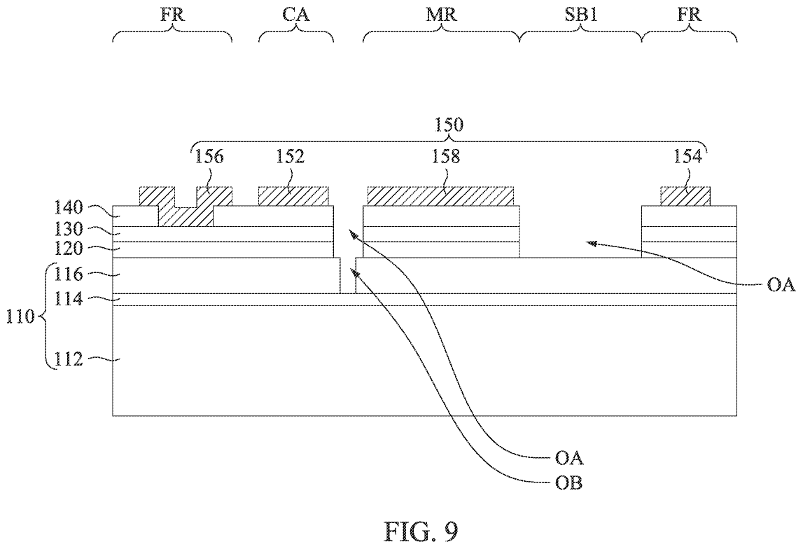

Reference is made to FIG. 9. Opening OB are etched in the semiconductor layer 116 exposed by the openings OA. Through the formation of the openings OA and OB, the first cantilever region CA, the second cantilever region CB, the mirror region MR, the shock buffer regions SB1, SB2, the frame region FR, the connection regions SPA1 and SPA2, and the connection regions SPB1 and SPB2 are defined.

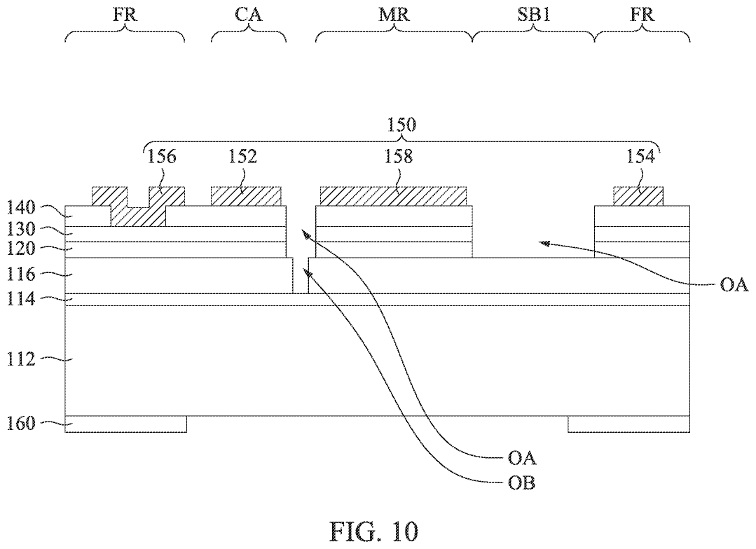

Reference is made to FIG. 10. A backside metal layer 160 is deposited at a backside of the semiconductor substrate 110, and being patterned to cover the frame region FR and exposing other regions. The backside metal layer 160 may include suitable metals, such as aluminum (Al), the like, or the combination thereof.

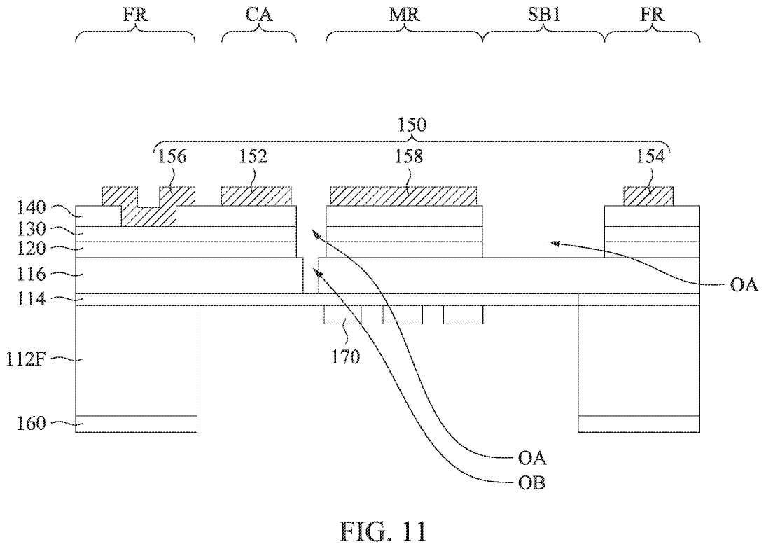

Reference is made to FIG. 11. A two-step etching process is performed to remove a portion of the base substrate 112 exposed by the backside metal layer 160, leaving a frame 112F and a rib structure 170 on the backside of the dielectric layer 114. The two-step etching process may include a first dry etch process and a second dry etch process following the second dry etch process. A photomask defining a rib pattern may be formed over the backside of the base substrate 112 through a photolithography process. The first dry etch process may etch the base substrate 112 with a suitable depth through the photomask, thereby forming a rib pattern in the base substrate 112. After the first dry etch process, the base substrate 112 has a rib pattern over the backside of the base substrate 112. Subsequently, the photomask is removed by suitable stripping or ashing process. Then, the second dry etch process is performed to etch the base substrate 112 using the backside metal layer 160 as an etch mask until the dielectric layer 114 is exposed, in which the rib structure 170 remains when the dielectric layer 114 is exposed. The first and second dry etch processes may be RIE or other suitable etching process.

The rib structure 170 is formed on a backside of the dielectric layer 114 in the mirror region MR, to provide a structural support to the mirror region MR, thereby maintaining a flatness of the mirror region MR. The rib structure 170 may be one or more rings, one or more straight lines, the like, or the combination thereof. A sum size of the rib structure 170 is smaller than the mirror region MR.

Reference is made to FIGS. 12A and 12B. After the formation of the rib structure 170, parts of the dielectric layer 114 exposed by the frame 112F and the rib structure 170 is removed by a backside oxide removal process. The backside oxide removal process may include suitable etching process. Through the backside oxide removal process, the mirror region MR is suspended, for example being spaced apart from the frame region FR by the first cantilever region CA, the second cantilever region CB, and the shock buffer regions SB1, SB2. And, the connection regions (transmission springs) SPA1, SPA2, SPB1, and SPB2 and the shock buffer regions SB1 and SB2 may include silicon material, being free of the dielectric layer 120, the first bottom electrode layer 130, the piezoelectric layer 140, and the top electrode layer 150.

Through the fabrication step, a MEMS device is formed. Reference is made to FIGS. 4, 12A, and 12B. The MEMS device includes a frame 112F, a dielectric layer 114, a semiconductor layer 116, a dielectric layer 120, a first bottom electrode layer 130, a piezoelectric layer 140, and a top electrode layer 150, a backside metal layer 160, and a rib structure 170. The dielectric layer 114, the semiconductor layer 116, the dielectric layer 120, the first bottom electrode layer 130, the piezoelectric layer 140, and the top electrode layer 150 are supported by the frame 112F. The top electrode layer 150 has separated electrodes 152-158. The backside metal layer 160 is formed on a backside of the frame 112F.

Openings O1 may be located between the mirror region MR and the first cantilever region CA, between the mirror region MR and the second cantilever region CB, between the mirror region MR and the connection regions (transmission springs) SPA1 and SPA2, and between the mirror region MR and the connection regions (transmission springs) SPB1 and SPB2. Openings 02 may be located between the frame region FR and the first cantilever region CA, between the frame region FR and the second cantilever region CB, between the frame region FR and the connection regions (transmission springs) SPA1 and SPA2, and between the mirror region MR and the connection regions (transmission springs) SPB1 and SPB2. The openings O1 and 02 may be a combination of the openings OA and OB.

Scanning mirrors with tapered actuators, transmission springs, and mirror plate were provided. Each actuator was covered by piezoelectric material film. When giving an AC bias, the piezoelectric material on actuators will deform and provide the driving force. The actuators will then apply load on transmission springs to drive the mirror. Hence, the force transferring capability of springs will directly affect the performance of scanning mirrors. Besides, springs structure also play a critical role to mitigate the maximum stress of devices. Various types of transmissions springs can be used to enhance the performance of mirrors.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that by designing the shape and dimension of springs, the stress on springs could be effectively reduced while maintaining great force transferring capability. Another advantage is that shock buffers are designed with suitable thickness to increase the out-of-plane stiffness of devices and mitigate the wobbling phenomenon of mirror plate when driving at large scanning angle. Still another advantage is that by using thinner/narrower shock buffer, the wobbling issue can be prevented, and the negative effect (restrain the rotation of mirror) caused by the reaction force from anchor can be reduced.

In some embodiments of the present disclosure, a microelectromechanical systems (MEMS) device includes a mirror structure; a frame; a first cantilever, comprising a first bottom electrode, a first piezoelectric layer over the first bottom electrode, a first top electrode over the first piezoelectric layer; a second cantilever, comprising a second bottom electrode, a second piezoelectric layer over the second bottom electrode, a second top electrode over the second piezoelectric layer, wherein the mirror structure is suspended in the frame by the first cantilever and the second cantilever; a first transmission spring connecting the first cantilever to a first end of the mirror structure; a second transmission spring connecting the second cantilever to the first end of the mirror structure; a third transmission spring connecting the first cantilever to a second end of the mirror structure; and a fourth transmission spring connecting the second cantilever to the second end of the mirror structure.

In some embodiments of the present disclosure, a MEMS device includes a mirror structure; a frame; a first cantilever, wherein the first cantilever has a first side adjoining the frame and a second side facing the mirror structure, the first side of the first cantilever is wider than the second side of the first cantilever and the mirror structure in a top view; a second cantilever, wherein the mirror structure is suspended in the frame by the first cantilever and the second cantilever; a first transmission spring connecting the first cantilever to the mirror structure; and a second transmission spring connecting the second cantilever to the mirror structure.

In some embodiments of the present disclosure, a method for forming a MEMS device is provided. The method includes depositing a bottom electrode layer over a semiconductor layer; depositing a piezoelectric layer over the bottom electrode layer; depositing a top electrode layer over the piezoelectric layer; patterning the top electrode layer into at least a first top electrode, a second top electrode, and a mirror, wherein the first top electrode has a first side facing away from the mirror and a second side facing the mirror, the first side of the first top electrode is wider than the second side of the first top electrode and the mirror in a top view; removing a portion of the piezoelectric layer and a portion of the bottom electrode layer from a first connection region and a second connection region of the semiconductor layer; and etching the semiconductor layer to define a first cantilever region, a second cantilever region, a mirror region, a frame region, the first connection region, and the second connection region of the semiconductor layer, wherein the mirror region in the frame region is suspended by the first cantilever region and the second cantilever region, the first connection region connects the first cantilever region to the mirror region, and the second connection region connects the second cantilever region to the mirror region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A microelectromechanical systems (MEMS) device, comprising:
a mirror structure;
a frame;
a first cantilever, comprising a first bottom electrode, a first piezoelectric layer over the first bottom electrode, a first top electrode over the first piezoelectric layer;
a second cantilever, comprising a second bottom electrode, a second piezoelectric layer over the second bottom electrode, a second top electrode over the second piezoelectric layer, wherein the mirror structure is suspended in the frame by the first cantilever and the second cantilever;
a first transmission spring connecting the first cantilever to a first end of the mirror structure;
a second transmission spring connecting the second cantilever to the first end of the mirror structure;
a third transmission spring connecting the first cantilever to a second end of the mirror structure; and
a fourth transmission spring connecting the second cantilever to the second end of the mirror structure.

2. The MEMS device of claim 1, wherein the first transmission spring comprises:
a first portion connected to the first cantilever, wherein the first portion of the first transmission spring extends substantially a direction parallel with a rotation axis of the mirror structure;
a second portion connected to the first end of the mirror structure, wherein the second portion of the first transmission spring extends substantially along the rotation axis of the mirror structure; and
a third portion connecting the first portion of the first transmission spring to the second portion of the first transmission spring.

3. The MEMS device of claim 2, wherein a length of the first portion of the first transmission spring is greater than a length of the second portion of the first transmission spring.

4. The MEMS device of claim 1, further comprising:
a first shock buffer connecting the frame to the first end of the mirror structure; and
a second shock buffer connecting the frame to the second end of the mirror structure.

5. The MEMS device of claim 4, wherein the first and second transmission springs are in contact with the first shock buffer.

6. The MEMS device of claim 4, wherein the third and fourth transmission springs are in contact with the second shock buffer.

7. The MEMS device of claim 4, wherein a width of the first shock buffer is less than a width of the first transmission spring.

8. The MEMS device of claim 4, wherein a width of the first shock buffer is substantially equal to a width of the first transmission spring.

9. A MEMS device, comprising:
a mirror structure;
a frame;
a first cantilever, wherein the first cantilever has a first side adjoining the frame and a second side facing the mirror structure, the first side of the first cantilever is wider than the second side of the first cantilever and the mirror structure in a top view;
a second cantilever, wherein the mirror structure is suspended in the frame by the first cantilever and the second cantilever;
a first transmission spring connecting the first cantilever to the mirror structure; and
a second transmission spring connecting the second cantilever to the mirror structure.

10. The MEMS device of claim 9, wherein the first side of the first cantilever is wider than the mirror structure in the top view.

11. The MEMS device of claim 9, wherein the first transmission spring comprises:
a first portion connected to the first cantilever, wherein the first portion of the first transmission spring extends substantially a direction parallel with a rotation axis of the mirror structure;
a second portion connected to the mirror structure, wherein the second portion of the first transmission spring extends substantially along the rotation axis of the mirror structure; and
a third portion connecting the first portion of the first transmission spring to the second portion of the first transmission spring.

12. The MEMS device of claim 11, wherein a length of the first portion of the first transmission spring is greater than a length of the second portion of the first transmission spring.

13. The MEMS device of claim 9, wherein the second side of the first cantilever has a concave profile in the top view.

14. The MEMS device of claim 9, wherein the second cantilever has a third side adjoining the frame and a fourth side facing the mirror structure, the third side of the second cantilever is wider than the fourth side of the second cantilever and the mirror structure in the top view.

15. The MEMS device of claim 14, wherein the fourth side of the second cantilever has a concave profile in the top view.

16. The MEMS device of claim 9, further comprising:
a shock buffer connecting the frame to the mirror structure and in contact with first transmission spring.

17. The MEMS device of claim 16, wherein a width of the shock buffer is less than a width of the first transmission spring.

18. A method for forming a MEMS device, comprising:
depositing a bottom electrode layer over a semiconductor layer;
depositing a piezoelectric layer over the bottom electrode layer;
depositing a top electrode layer over the piezoelectric layer;
patterning the top electrode layer into at least a first top electrode, a second top electrode, and a mirror, wherein the first top electrode has a first side facing away from the mirror and a second side facing the mirror, the first side of the first top electrode is wider than the second side of the first top electrode and the mirror in a top view;
removing a portion of the piezoelectric layer and a portion of the bottom electrode layer from a first connection region and a second connection region of the semiconductor layer; and
etching the semiconductor layer to define a first cantilever region, a second cantilever region, a mirror region, a frame region, the first connection region, and the second connection region of the semiconductor layer, wherein the mirror region in the frame region is suspended by the first cantilever region and the second cantilever region, the first connection region connects the first cantilever region to the mirror region, and the second connection region connects the second cantilever region to the mirror region.

19. The method of claim 18, wherein the second top electrode has a first side facing away from the mirror and a second side facing the mirror, the first side of the second top electrode is wider than the second side of the second top electrode and the mirror in the top view.

20. The method of claim 18, wherein etching the semiconductor layer further defines a shock buffer region connecting the mirror region to the frame region and in contact with the first connection region.
